(19) United States
(12) Patent Application Publication
(10) Pub. No.: US 2025/0244627 A1
(43) Pub. Date: Jul. 31, 2025

(54) DISPLAY APPARATUS AND ARRAY SUBSTRATE

(71) Applicant: Japan Display Inc., Tokyo (JP)

(72) Inventors: Masateru MORIMOTO, Tokyo (JP); Teppei YAMADA, Tokyo (JP)

(73) Assignee: Japan Display Inc., Tokyo (JP)

(21) Appl. No.: 19/034,707

(22) Filed: Jan. 23, 2025

(30) Foreign Application Priority Data
Jan. 31, 2024 (JP) 2024-013508

(51) Int. Cl. G02F 1/1368; G02F 1/1362; H10D 86/40

(52) U.S. Cl. CPC G02F 1/1368; G02F 1/136286; H10D 86/441; H10D 86/451

(57) ABSTRACT

A display apparatus includes a semiconductor layer, a signal line provided on the semiconductor layer, a first insulating portion provided on a side of the signal line, a second insulating portion provided on the first insulating portion and the signal line, and a protective layer provided on the second insulating portion. In plan view, a first region in which the protective layer is provided includes a second region in which the signal line is connected to the semiconductor layer, and a third region arranged in a surrounding of the second region in which the semiconductor layer is covered by the first insulating portion.

### CROSS REFERENCES TO RELATED APPLICATIONS

The present application claims priority to Japanese Patent Application No. 2024-013508 filed on Jan. 31, 2024, the disclosure of which is incorporated herein by reference.

### BACKGROUND

The present invention relates to a display apparatus and an array substrate.

Japanese Patent No. 6776060 (Patent Document 1) discloses a display apparatus including a switching element including a semiconductor layer and a signal line, with a conductive protective layer provided between the semiconductor layer and the signal line, and the semiconductor layer and the signal line being electrically connected via the protective layer.

### SUMMARY

In a display apparatus and an array substrate, it is expected to prevent disconnections in a semiconductor layer.

A display apparatus according to an embodiment includes a semiconductor layer, a signal line provided on the semiconductor layer, a first insulating portion provided on a side of the signal line, a second insulating portion provided on the first insulating portion and the signal line, and a protective layer provided on the second insulating portion. In plan view, a first region in which the protective layer is provided includes a second region in which the signal line is connected to the semiconductor layer, and a third region arranged in a surrounding of the second region in which the semiconductor layer is covered by the first insulating portion.

An array substrate according to an embodiment includes a semiconductor layer, a signal line provided on the semiconductor layer, a first insulating portion provided on a side of the signal line, a second insulating portion provided on the first insulating portion and the signal line, and a protective layer provided on the second insulating portion. In plan view, a first region in which the protective layer is provided includes a second region in which the signal line is connected to the semiconductor layer, and a third region arranged in a surrounding of the second region in which the semiconductor layer is covered by the first insulating portion.

### BRIEF DESCRIPTION OF THE DRAWINGS

FIG. 1 is an exploded perspective view illustrating a schematic configuration example of a display apparatus.

FIG. 2 is a plan view illustrating a schematic configuration of a display panel.

FIG. 3 is a plan view illustrating an example of a planar layout of subpixels.

FIG. 4 is a schematic plan view illustrating a protective layer provided in a subpixel.

FIG. 5 is a schematic cross-sectional view taken along line A-A in FIG. 4.

FIG. 6 is a schematic cross-sectional view taken along line B-B in FIG. 4 before the protective layer is formed.

FIG. 7 is a schematic cross-sectional view taken along line B-B in FIG. 4 after the protective layer is formed.

FIG. 8 is a schematic cross-sectional view taken along line C-C of FIG. 4.

FIG. 9 is a flowchart illustrating an example of formation of the protective layer.

FIG. 10 is a cross-sectional view illustrating a configuration example of a display apparatus of a comparative example.

FIG. 11 is a plan view schematically illustrating another example of the protective layer.

FIG. 12 is a plan view schematically illustrating another example of the protective layer.

FIG. 13 is a plan view schematically illustrating another example of the protective layer.

### DESCRIPTIONS OF THE PREFERRED EMBODIMENTS

Hereinafter, an embodiment will be described with reference to the drawings.

Note that the present disclosure is merely an example, and any modifications that a person skilled in the art can easily conceive of while maintaining the gist of the present disclosure are naturally included within the scope of the present disclosure.

In addition, for the clearer description, the drawings may illustrate the width, thickness, shape, etc. of each part schematically compared to the actual embodiment, but these are merely examples and do not limit the interpretation of the present disclosure. In the present specification and each drawing, elements similar to those illustrated in the previous drawings are given the same reference numerals, and detailed descriptions thereof may be omitted as appropriate.

In the present embodiment, a liquid crystal display apparatus having liquid crystal display elements is disclosed as an example of a display apparatus. However, the embodiment does not preclude application of the technical ideas disclosed in the embodiment to display apparatuses having other types of display elements, such as organic electroluminescence display elements, micro LEDs, mini LEDs, and the like. Furthermore, the technical ideas disclosed in the embodiment can also be applied to an array substrate and an electronic device having sensor elements such as capacitive sensors and optical sensors.

### <Overall Configuration of Liquid Crystal Display Apparatus>

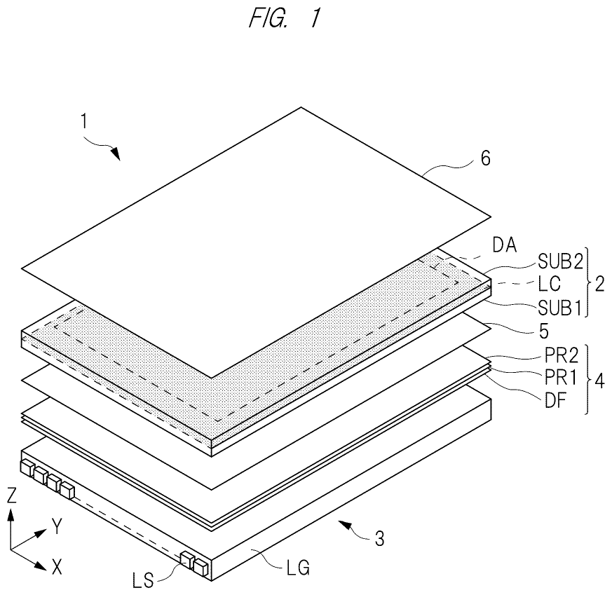

FIG. 1 is an exploded perspective view illustrating a schematic configuration example of a liquid crystal display apparatus 1.

As illustrated in FIG. 1, the X direction, the Y direction, and the Z direction are defined. The X direction, the Y direction, and the Z direction are perpendicular to one another, but may intersect at an angle other than a perpendicular angle. Viewing the liquid crystal display apparatus 1 and the components thereof parallel to the Z direction is referred to as “in plan view”. The direction indicated by the Z-direction arrow may be referred to as “upward” and the opposite direction as “downward”.

In FIG. 1, the liquid crystal display apparatus 1 includes a display panel 2 and a backlight 3. For example, the backlight 3 can be configured as a side-edge type backlight including a light guide LG facing the display panel 2 and a plurality of light-emitting elements LS arranged at positions facing the side surfaces of the light guide LG. However, the backlight 3 is not limited thereto, and backlights of various configurations that can supply the light necessary for image display can be employed.

The planar shapes of the display panel 2 and the light guide LG are formed, for example, in a rectangular shape with short sides along the X direction and long sides along the Y direction, but are not limited to a rectangular shape and may be in other shapes.

The display panel 2 is a translucent liquid crystal panel and includes, for example, an array substrate SUB1, a counter substrate SUB2 facing the array substrate SUB1, and a liquid crystal layer LC sealed between the array substrate SUB1 and the counter substrate SUB2. The display panel 2 thus configured has, for example, a rectangular display area DA.

The liquid crystal display apparatus 1 further includes an optical sheet group 4, a polarizing plate 5, and a polarizing plate 6. The optical sheet group 4 is disposed between the light guide LG and the display panel 2. For example, the optical sheet group 4 includes a diffusion sheet DF that diffuses the light emitted from the light guide LG, and a prism sheet PR1 and a prism sheet PR2 each having a number of prisms formed thereon.

The polarizing plate 5 is disposed between the optical sheet group 4 and the array substrate SUB1. On the other hand, the polarizing plate 6 is disposed above the counter substrate SUB2. Here, the polarizing axis of the polarizing plate 5 and the polarizing axis of the polarizing plate 6 are in a cross-Nicol relationship, being orthogonal to each other.

The liquid crystal display apparatus 1 thus configured can be used in various types of devices, such as a head mounted display, an in-vehicle device, a smartphone, a tablet terminal device, a mobile phone, a personal computer, a television receiver, and a game device.

### <Display Panel Configuration>

Next, the configuration of the display panel 2 will be described.

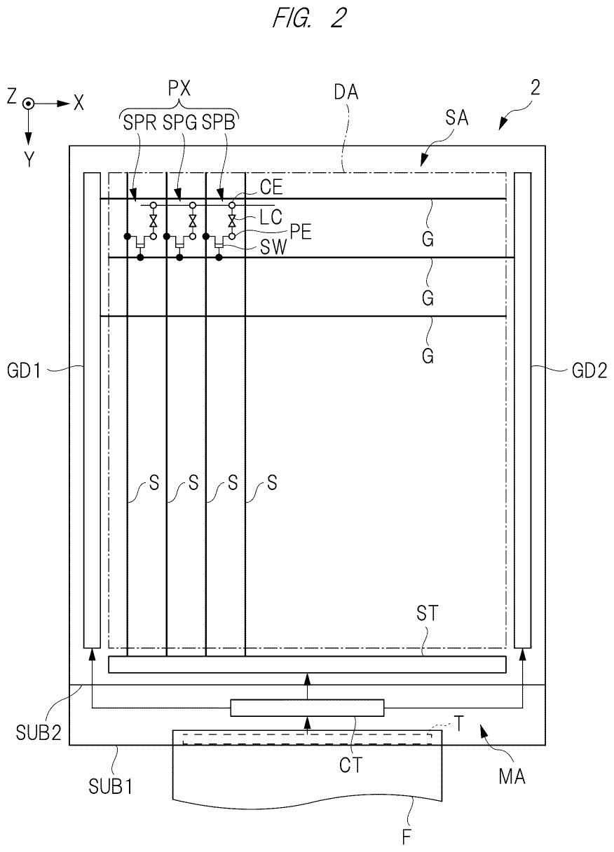

FIG. 2 is a plan view illustrating a schematic configuration of the display panel 2.

In FIG. 2, the display panel 2 includes the display area DA and a surrounding area SA surrounding the display area DA. For example, as illustrated in FIG. 2, the lower side of the array substrate SUB1 protrudes in the Y direction beyond the counter substrate SUB2. Due to the configuration, the array substrate SUB1 has a mounting area MA that does not overlap with the counter substrate SUB2 in plan view. The mounting area MA forms a part of the surrounding area SA.

In the display area DA, a plurality of pixels PX is arranged in a matrix. A pixel PX includes a plurality of subpixels. For example, in FIG. 2, the pixel PX includes a red subpixel SPR, a green subpixel SPG, and a blue subpixel SPB. However, the pixel PX is not limited to this configuration, and may be configured to include subpixels of other colors, typically white.

As illustrated in FIG. 2, the display panel 2 includes a plurality of scanning lines G, a plurality of signal lines S (video lines), a scanning driver GD1, a scanning driver GD2, and a selector circuit ST. The plurality of scanning lines G extends in the X direction and are aligned in the Y direction. On the other hand, the plurality of signal lines S extends in the Y direction and are aligned in the X direction. Each of the plurality of scanning lines G is connected to the scanning driver GD1 or the scanning driver GD2. On the other hand, each of the plurality signal lines S is connected to the selector circuit ST.

Next, as illustrated in FIG. 2, a controller CT is mounted in the mounting area MA. Further, a terminal portion T is provided in the mounting area MA, and a flexible substrate F is connected to the terminal portion T. The controller CT may be mounted on the flexible substrate F. The controller CT is configured of, for example, an IC chip and circuit elements.

Various types of signals transmitted from an electronic device in which the liquid crystal display apparatus 1 is mounted are output to the controller CT via an integrated circuit mounted on the flexible substrate F. The controller CT receives these signals, supplies a video signal to the selector circuit ST, and controls the scanning driver GD1, the scanning driver GD2, and the selector circuit ST.

Each of the scanning driver GD1 and the scanning driver GD2 sequentially supplies scanning signals to the plurality of scanning lines G. On the other hand, the selector circuit ST sequentially supplies the video signals input from the controller CT to the signal lines S.

The pixel PX is configured to include a pixel electrode PE, a switching element SW (thin film transistor), and a common electrode CE to which a common potential is supplied. The switching element SW is connected to the pixel electrode PE, the scanning line G and the signal line S.

For example, when the switching element SW is formed of a thin film transistor (field effect transistor), the gate of the thin film transistor is electrically connected to the scanning line G. Further, the source of the thin film transistor is electrically connected to the signal line S, while the drain of the thin film transistor is electrically connected to the pixel electrode PE.

When a scanning signal is supplied to the scanning line G, the thin film transistor is turned On, and the video signal supplied to the signal line S is supplied to the pixel electrode PE. On the other hand, the common electrode CE is formed across the plurality of subpixels, and when a video signal is supplied to the pixel electrode PE, a potential difference occurs between the pixel electrode PE and the common electrode CE. The electric field thus occurred acts on the liquid crystal layer LC, and as a result, the alignment direction of a plurality of liquid crystal molecules that forms the liquid crystal layer LC is controlled.

For example, in the so-called “vertical electric field method” in which the pixel electrode PE is formed on the array substrate while the common electrode CE is formed on a counter substrate, and the liquid crystal layer LC is interposed between the pixel electrode PE and the common electrode CE, the alignment direction of the plurality of liquid crystal molecules that forms the liquid crystal layer LC is controlled by the vertical electric field occurred between the pixel electrode PE and the common electrode CE.

On the other hand, in the so-called “horizontal electric field method”, for example, in which the pixel electrode PE and the common electrode CE are formed on the array substrate, and a horizontal electric field (fringe electric field) leaking out of a slit provided in the common electrode CE is utilized, the alignment direction of the plurality of liquid crystal molecules that forms the liquid crystal layer LC arranged above the array substrate is controlled by the horizontal electric field leaking out of the slit.

Accordingly, the “vertical electric field method” and the “horizontal electric field method” represent methods for controlling the alignment direction of liquid crystal molecules. For example, the “horizontal electric field method” has the advantage of allowing a wider viewing angle compared to the “vertical electric field method”. In the present embodiment, the “horizontal electric field type” is adopted, and the scanning lines G, the signal lines S, the scanning driver GD1, the scanning driver GD2, the selector circuit ST, the switching elements SW, the pixel electrodes PE, and the common electrodes CE are formed on the array substrate SUB1.

### <Plane Layout Configuration of Subpixels>

Next, a planar layout configuration of the subpixels will be described.

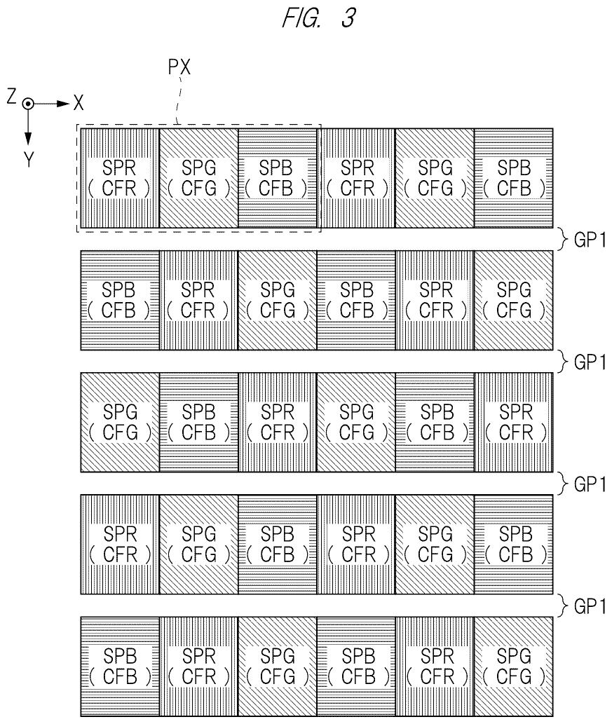

FIG. 3 is a plan view illustrating an example of the planar layout of the subpixels.

In FIG. 3, the subpixels include the subpixel SPR, the subpixel SPG, and the subpixel SPB. While a red color filter CFR is disposed in the subpixel SPR, a green color filter CFG is disposed in the subpixel SPG. And, a blue color filter CFB is disposed in the subpixel SPB.

As illustrated in FIG. 3, the subpixels SPR, SPG, and SPB are arranged in this order in the X direction. Also, the subpixels SPR, SPB, and SPG are arranged in this order in the Y direction. Accordingly, the subpixels SPR are arranged in a diagonal direction intersecting both the X direction and the Y direction. Similarly, the subpixels SPG are arranged in the diagonal direction, and the subpixels SPB are also arranged in a diagonal direction.

The color filters CFR, CFG, and CFB are arranged in a dot shape (island shape) with respect to the subpixels SPR, SPG, and SPB, respectively.

For example, gaps GP1 are formed between the color filter CFR and the color filter CFG, between the color filter CFG and the color filter CFB, and between the color filter CFB and the color filter CFR, that are adjacent in the Y direction.

It should be noted that the planar layout of the subpixels SPR, SPG, and SPB and the color filters CFR, CFG, and CFB is not limited to the planar layout illustrated in FIG. 3.

For example, the subpixels SPR may be arranged in the Y direction, the subpixels SPG may be arranged in the Y direction, and the subpixels SPB may be arranged in the Y direction, with the row of subpixels SPR, the row of subpixels SPG, and the row of subpixels SPB aligned in order in the X direction.

As described above, the liquid crystal display apparatus 1 of the present embodiment has a so-called “Color Filter on Array (COA) structure” in which all of the color filters CFR, CFG, and CFB are arranged on the array substrate SUB1. According to the “COA structure”, the color filters and the subpixels are provided on the same array substrate SUB1. Due to this, according to the “COA structure”, the high-definition liquid crystal display apparatus 1 can be implemented without being affected by misalignment between the array substrate SUB1 and the counter substrate SUB2.

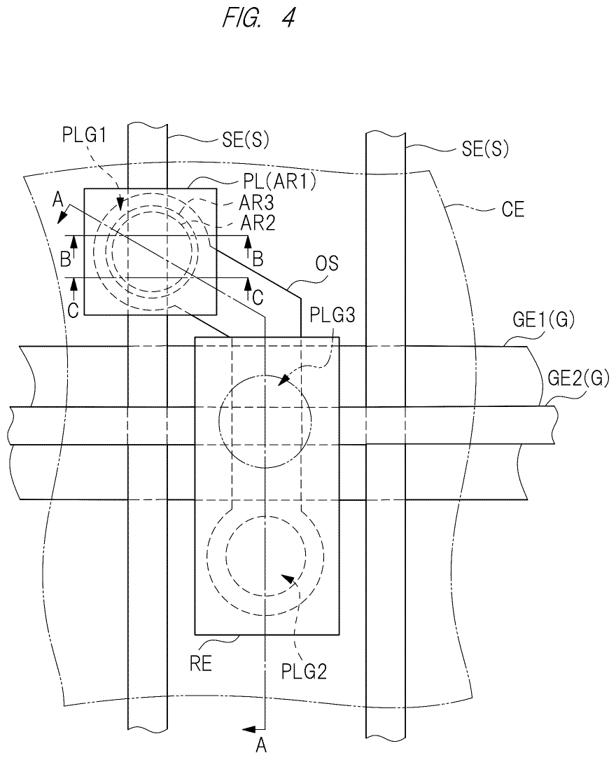

FIG. 4 is a schematic plan view illustrating a protective layer PL provided in a subpixel. In FIG. 4, an opening region formed in the subpixel, a slit provided in the opening region, a conductive film TML and insulating layers IL1 to IL7, which will be described later with reference to FIG. 5, and the like are omitted.

FIG. 4 illustrates a gate electrode GE1 (first gate electrode) and a gate electrode GE2 (second gate electrode) extending in the X direction, and two source electrodes SE extending in the Y direction intersecting these gate electrodes GE1 and GE2. The gate electrodes GE1 and GE2 form the above described scanning lines G. The source electrodes SE form the above described signal lines S.

The source electrode SE includes a contact portion PLG1 (first contact portion). The contact portion PLG1 is connected to a semiconductor layer OS being a thin film transistor. The semiconductor layer OS forms the switching element SW described above. Accordingly, the contact portion PLG1 has a function of electrically connecting the semiconductor layer OS and the source electrode SE.

A part of the upper surface of the source electrode SE is covered with a protective layer PL. The protective layer PL has, for example, a rectangular shape in plan view, as illustrated in FIG. 4. A first region AR1 in which the protective layer PL is provided includes a second region AR2 in which the semiconductor layer OS and the source electrode SE are connected, and a third region AR3 arranged in the surrounding of the second region AR2 and in which the semiconductor layer OS is covered with an insulating portion IP1 (not illustrated in FIG. 4). Forming the protective layer PL in a rectangular shape allows for easier dimensional control which simplifies the manufacturing process of the liquid crystal display apparatus 1. The shape of the protective layer PL is not limited to a rectangular shape. The protective layer PL is made of a translucent conductive material such as indium tin oxide (ITO). The method of forming the protective layer PL will be described later.

The semiconductor layer OS extends so as to intersect with the gate electrodes GE1 and GE2. The semiconductor layer OS is provided above the gate electrode GE1 and includes a portion provided below the gate electrode GE2. The semiconductor layer OS is connected to a relay electrode RE (first electrode) at a contact portion PLG2. Specifically, the contact portion PLG2 (second contact portion) has a function of electrically connecting the semiconductor layer OS and the relay electrode RE. The relay electrode RE is made of a translucent conductive material such as ITO.

Next, as illustrated in FIG. 4, for example, the common electrode CE is provided so as to overlap planarly with all of the elements such as the gate electrodes GE1 and GE2 and the source electrode SE. In an opening region (not illustrated), a slit (not illustrated) is provided in the common electrode CE. Moreover, a contact portion PLG3 (third contact portion) is provided on the relay electrode RE. The contact portion PLG3 has a function of electrically connecting the pixel electrode PE and the relay electrode RE.

Here, for example, an electric field that occurs when a potential difference is occurred between the common electrode CE and the pixel electrode PE leaks out of a slit (not illustrated) provided in the common electrode CE. As a result, the alignment direction of the plurality of liquid crystal molecules forming the liquid crystal layer LC disposed above the array substrate SUB1 is controlled by the horizontal electric field leaking out of the slit (not illustrated). That is, the slit (not illustrated) provided in the common electrode CE has a function of applying a horizontal electric field to the liquid crystal layer LC for controlling the alignment direction of the plurality of liquid crystal molecules.

Accordingly, the planar layout configuration of the subpixels is implemented.

### <Cross-Sectional Configuration of Subpixel>

Next, a cross-sectional configuration of the subpixel will be described.

FIG. 5 is a schematic cross-sectional view taken along line A-A in FIG. 4. Note that FIG. 5 is not an exact representation of the cross-section along line A-A in FIG. 4, but rather a schematic cross-sectional view. For example, in FIG. 5, while the conductive film TML and the insulating layers IL1 to IL7 are illustrated, these conductive film TML and insulating layers IL1 to IL7 are not illustrated in FIG. 4.

In FIG. 5, the insulating layer IL1 is formed on a glass substrate 10 having a translucent property. The insulating layer IL2 is formed on the insulating layer IL1. In the present embodiment, the glass substrate 10 is made of glass, but is not limited thereto and may be made of a resin material such as polyimide resin. The insulating layer IL1 and the insulating layer IL2 are made from an inorganic insulating film such as a silicon nitride film or a silicon oxide film.

Subsequently, as illustrated in FIG. 5, the gate electrode GE1 of a thin film transistor (field effect transistor) being a switching element is formed on the insulating layer IL2. The gate electrode GE1 functions as a scanning line G. The gate electrode GE1 is made of, for example, a metal material. The gate electrode GE1 may have a single-layer structure made of a single metal material, or may have a multi-layer structure in which different types of metal materials are laminated.

Next, the insulating layer IL3 is formed on the insulating layer IL2 so as to cover the gate electrode GE1. The semiconductor layer OS is formed on the insulating layer IL3. For example the insulating layer IL3 is made from an inorganic insulating film such as a silicon nitride film or a silicon oxide film. On the other hand, the semiconductor layer OS is made from an amorphous silicon film or an oxide semiconductor film.

The semiconductor layer OS functions as a channel of the thin film transistor. That is, a channel is formed in the semiconductor layer OS based on a gate voltage applied to the gate electrode GE1. For example, when a gate voltage equal to or higher than a threshold voltage is applied to the gate electrode GE1, a channel is formed in the semiconductor layer OS. On the other hand, when a gate voltage less than the threshold value is applied to the gate electrode GE1, the channel formed in the semiconductor layer OS disappears.

This makes it possible to control the On/Off operation of the thin film transistor based on the gate voltage applied to the gate electrode GE1.

For example, the semiconductor layer OS is preferably formed of an oxide semiconductor film. This is because a thin film transistor using an oxide semiconductor film as a channel has higher electron mobility than a thin film transistor using an amorphous silicon film as a channel, and has the advantage of having a very low off-leak current.

Subsequently, as illustrated in FIG. 5, the insulating layer IL4 is formed on the insulating layer IL3 so as to cover the semiconductor layer OS. And the insulating layer IL4 is formed on the gate electrode GE2. The insulating layer IL4 is made from an inorganic insulating film such as a silicon nitride film or a silicon oxide film. On the other hand, the gate electrode GE2 is made of, for example, a metal material.

Accordingly, the thin film transistor includes the gate electrode GE1 and the gate electrode GE2 disposed so as to interpose the semiconductor layer OS therebetween from above and below. In this configuration, for example, a channel can be formed on the lower surface of the semiconductor layer OS by applying a gate voltage equal to or greater than the threshold voltage to the gate electrode GE1 disposed below the semiconductor layer OS, and a channel can also be formed on the upper surface of the semiconductor layer OS by applying a gate voltage equal to or greater than the threshold voltage to the gate electrode GE2 disposed above the semiconductor layer OS.

That is, in the thin film transistor of the present embodiment, channels can be formed on both the upper surface and the lower surface of the semiconductor layer OS, so that the current driving force of the thin film transistor can be improved. However, the configuration of the thin film transistor is not limited thereto, and the gate electrode GE2 may be omitted.

Next, the insulating layer IL5 is formed on the insulating layer IL4 so as to cover the gate electrode GE2. The source electrode SE is formed on the insulating layer IL5. The source electrode SE functions as a signal line S. Also, the source electrode SE or the signal line S is narrower than the width of the semiconductor layer OS. For example, the insulating layer IL5 is made from an inorganic insulating film such as a silicon nitride film or a silicon oxide film. On the other hand, the source electrode SE is made of, for example, a metal material.

As illustrated in FIG. 5, a contact hole CH1 is formed in the insulating layer IL4 and the insulating layer IL5 so as to extend through these insulating layers and reach the semiconductor layer OS. The insulating layer IL4 and the insulating layer IL5 form the insulating portion IP1 (first insulating portion). The cross-sectional shape of the contact hole CH1 is, for example, an inversely tapered shape in which the width narrows toward the semiconductor layer OS. In the contact hole CH1, the source electrode SE is electrically connected to the semiconductor layer OS via the contact portion PLG1. The cross-sectional shape of the source electrode SE including the contact portion PLG1 is, for example, a tapered shape in which the width widens toward the semiconductor layer OS.

Next, the insulating layer IL6 is formed on the insulating layer IL5 so as to cover the source electrode SE. For example, the insulating layer IL6 is made from an inorganic insulating film such as a silicon nitride film or a silicon oxide film. The insulating layer IL6 forms the insulating portion IP2 (second insulating portion). As illustrated in FIG. 5, a contact hole CH2 extending through the insulating layer IL6, the insulating layer IL5, and the insulating layer IL4 and reaching the semiconductor layer OS is formed. At this point, the relay electrode RE is formed extending from the inside of the contact hole CH2 onto the insulating layer IL6. In FIG. 5, the contact hole CH1 is formed at one end of the semiconductor layer OS, and the contact hole CH2 is formed at the other end of the semiconductor layer OS.

On the insulating layer IL6, the protective layer PL is provided in addition to the relay electrode RE. The protective layer PL is disposed away from the relay electrode RE. The protective layer PL is provided, for example, in a floating state on the insulating layer IL6. Here, a “floating” state means that it is not electrically connected to other members. Therefore, even if the protective layer PL is provided in the liquid crystal display apparatus 1, it is possible to prevent electrical influence on other conductive members. Further, disposing the protective layer PL in a floating state allows for eliminating the process of forming contact holes and the like which simplifies the manufacturing process. The protective layer PL may be unintentionally electrically connected to the source electrode SE through a gap formed in the insulating layer IL6. In addition, the protective layer PL may be electrically connected to the source electrode SE by utilizing, for example, a contact hole. This is because even if the protective layer PL is connected to the source electrode SE, the electrical influence is minimal.

Subsequently, the insulating layer IL7 is formed on the insulating layer IL6 so as to fill the inside of the contact hole CH2 and cover the relay electrode RE formed on a part of the insulating layer IL6 and the protective layer PL. For example, the insulating layer IL7 is also made from an inorganic insulating film such as a silicon nitride film or a silicon oxide film.

Accordingly, the contact portion PLG2 is formed, which has the relay electrode RE connected to the semiconductor layer OS in the contact hole CH2 and the insulating layer IL7 covering the relay electrode RE. The relay electrode RE includes the contact portion PLG2. The contact portion PLG2 extends through the insulating portion IP1 and the insulating portion IP2 and is electrically connected to the semiconductor layer OS. As a result, the relay electrode RE is electrically connected to the semiconductor layer OS via the contact portion PLG2. In other words, the relay electrode RE is electrically connected to the drain of the thin film transistor.

The protective layer PL is provided above the contact portion PLG1 included in the source electrode SE. The protective layer PL closes a gap GP2 formed between the insulating portion IP2 (insulating layer IL6) formed on the source electrode SE and the insulating portion IP2 formed on the insulating portion IP1. The protective layer PL will be described in detail later.

As illustrated in FIG. 5, the color filters CFB and CFG are formed on the insulating layer IL7. Accordingly, the “COA structure” is implemented in the present embodiment. Subsequently, an organic insulating film 100A is formed so as to cover the color filter CFB and the color filter CFG. The organic insulating film 100A is made of an organic material such as an acrylic resin. In the organic insulating film 100A and the insulating layer IL7, a contact hole CH3 is formed which extends through the organic insulating film 100A and the insulating layer IL7 and reaches the relay electrode RE. In the contact hole CH3, a plurality of types of components is embedded to form the contact portion PLG3 (third contact portion). Accordingly, the pixel electrode PE is electrically connected to the semiconductor layer OS (drain side) via the relay electrode RE at the contact portion PLG3. The contact portion PLG3 is connected to the relay electrode RE above the gate electrode GE2.

Next, the internal and external configuration of the contact portion PLG3 will be described.

In FIG. 5, the relay electrode RE is provided on the insulating layer IL6, and the insulating layer IL7 is disposed so as to cover the relay electrode RE. The color filter CFB and the color filter CFG are provided on the insulating layer IL7. In order to flatten the unevenness caused by the color filter CFB and the color filter CFG, the organic insulating film 100A is provided so as to cover the color filter CFB and the color filter CFG.

And, as illustrated in FIG. 5, in the organic insulating film 100A, the contact hole CH3 is formed which extends through the organic insulating film 100A and the insulating layer IL7 and reaches the relay electrode RE. A pixel electrode PE made of a translucent conductive material such as ITO is formed on the inner wall of the contact hole CH3. As illustrated in FIG. 5, the pixel electrode PE is electrically connected to the relay electrode RE at the bottom of the contact hole CH3. Further, in the contact hole CH3, a capacitive insulating film CI is formed in contact with the pixel electrode PE and the inner wall of the contact hole CH3. The capacitive insulating film CI is formed of, for example, a silicon nitride film. Subsequently, in the contact hole CH3, the conductive film TML in contact with the capacitive insulating film CI, the common electrode CE in contact with the conductive film TML, and an organic insulating film 100B in contact with the common electrode CE and filling the contact hole CH3 are formed.

Here, a capacitance is formed by the pixel electrode PE, the capacitive insulating film CI, and the common electrode CE, and when a potential difference occurs between the pixel electrode PE and the common electrode CE, an electric field is induced between the pixel electrode PE and the common electrode CE. The common electrode CE is provided with a slit (not illustrated), and the electric field leaks out of the slit to the outside of the capacitance. The alignment direction of the liquid crystal molecules is controlled based on the electric field leaking out of the slit.

The common electrode CE is made of a translucent conductive material such as ITO. In order to reduce the resistance of the common electrode CE, the conductive film TML is provided in contact with the common electrode CE. In other words, the conductive film TML has a function of reducing the resistance of the common electrode CE.

Next, in FIG. 5, above the organic insulating film 100A on which the contact portion PLG3 is formed, the liquid crystal layer LC is disposed via an alignment film 200A, and above the contact portion PLG3, a spacer SP is provided. A glass substrate is disposed on the liquid crystal layer LC via an alignment film 200B and an overcoat film OC.

Accordingly, the cross-sectional configuration of the subpixels is implemented.

### <Operation of Subpixel>

Next, the operation of the subpixel will be briefly described.

For example, when a scanning signal is supplied to the gate electrode GE1 and the gate electrode GE2 of the thin film transistor being one of the components of the subpixel, a gate voltage equal to or higher than a threshold voltage is applied to each of the gate electrode GE1 and the gate electrode GE2. Then, channels are formed on both the lower and upper surfaces of the semiconductor layer OS interposed between the gate electrode GE1 and the gate electrode GE2. This electrically connects the source and the drain of the thin film transistor, turning the thin film transistor On. At this point, for example, when a video signal is supplied to the source electrode SE of the thin film transistor, this video signal is transmitted to the relay electrode RE electrically connected to the drain of the semiconductor layer OS via the thin film transistor that is turned On. Thereafter, the video signal is transmitted from the relay electrode RE to the pixel electrode PE via the contact portion PLG3.

The capacitance formed from the pixel electrode PE, the common electrode CE, and the capacitive insulating film CI is formed inside and outside the contact portion PLG3, and a video signal is supplied to the pixel electrode PE that forms the capacitance. As a result, a potential difference occurs between the pixel electrode PE and the common electrode CE, and an electric field occurred based on the potential difference leaks out of the slit provided in the common electrode CE. As a result, the alignment direction of the plurality of liquid crystal molecules forming the liquid crystal layer LC disposed above the array substrate SUB1 is controlled by the horizontal electric field leaking out of the slit. Consequently, the transmission and blocking of light from the liquid crystal layer LC is controlled in the subpixel. Such control is performed in all subpixels arranged in the display area, enabling the display of an image in the display area DA.

### <Description of Protective Layer>

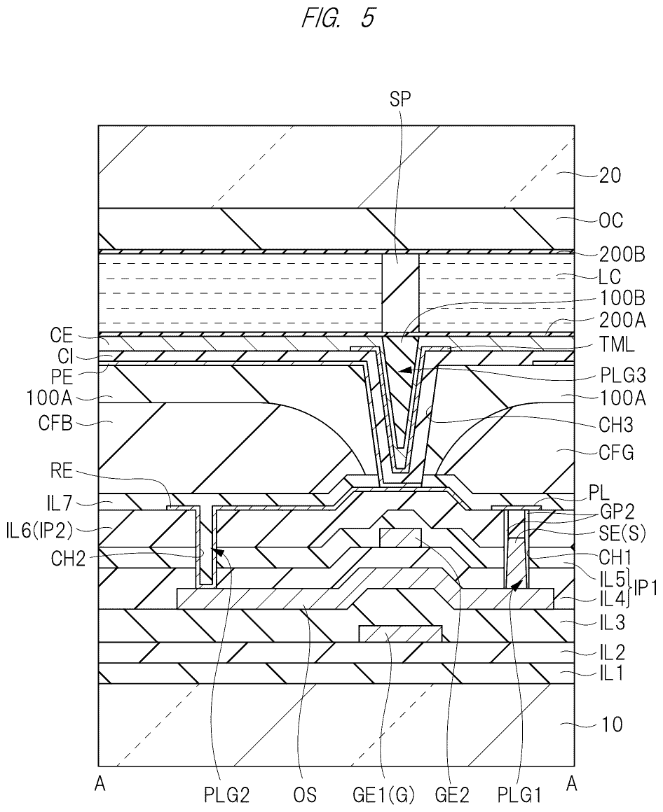

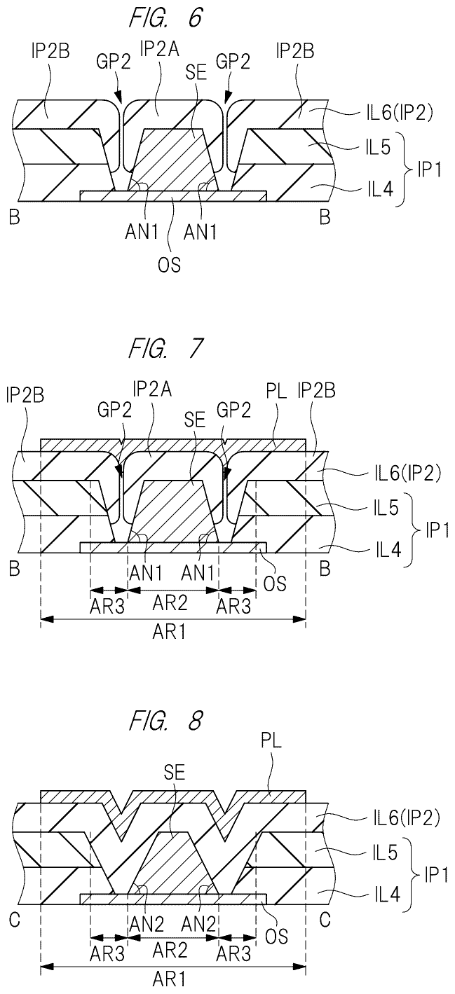

Next, the protective layer PL will be described. FIG. 6 is a schematic cross-sectional view taken along line B-B in FIG. 4 before the protective layer is formed. FIG. 7 is a schematic cross-sectional view taken along line B-B in FIG. 4 after the protective layer is formed.

As illustrated in FIG. 6, a configuration example used to explain the protective layer PL of the liquid crystal display apparatus 1 includes the semiconductor layer OS, the source electrode SE provided on the semiconductor layer OS, the insulating portion IP1 provided on the side of the source electrode SE, the insulating portion IP2 provided on the insulating portion IP1 and on the source electrode SE, and the protective layer PL (see FIG. 7) provided on the insulating portion IP2. The semiconductor layer OS, the source electrode SE, the insulating portion IP1, the insulating portion IP2, and the protective layer PL are provided, for example, on the array substrate SUB1 (see FIG. 1) not illustrated in FIG. 6.

The cross-sectional shape s of the source electrode SE including the contact portion PLG1 in the width direction is, for example, a tapered shape in which the width widens toward the semiconductor layer OS. In the source electrode SE, an angle AN1 of the portion forming the tapered shape with respect to the semiconductor layer OS is, for example, 70 degrees. The angle AN1 may be 70 degrees or more and less than 90 degrees. In other words, the angle AN1 is an angle at which an abnormality (gap GP2) occurs in the insulating portion IP2 (insulating layer IL6) formed on the insulating portion IP1. When the angle AN1 is a steep taper shape of 70 degrees or more and less than 90 degrees, the facing insulating portion IP1 may also be formed in a steep taper shape of 70 degrees or more and less than 90 degrees, similar to the source electrode SE. When the source electrode SE and the insulating portion IP1 are both formed in a highly tapered shape in this manner, the gap GP2 may be formed between the insulating portion IP2A formed on the source electrode SE and the insulating portion IP2B formed on the insulating portion IP1.

As illustrated in FIG. 7, the protective layer PL is formed so as to cover the insulating portion IP2 (insulating layer IL6). The first region AR1 in which the protective layer PL is provided includes the second region AR2 in which the source electrode SE is connected to the semiconductor layer OS, and the third region AR3 arranged in the surrounding of the second region AR2 and in which the semiconductor layer OS is covered with the insulating portion IP1. Accordingly, the protective layer PL covers the gap GP2 formed between the insulating portion IP2A formed on the source electrode SE and the insulating portion IP2B formed on the insulating portion IP1. The third region AR3 includes a region that includes at least the gap GP2 in plan view.

FIG. 8 is a schematic cross-sectional view taken along line C-C of FIG. 4.

As illustrated in FIG. 8, the cross-sectional shape of the source electrode SE in the width direction is a tapered shape in which the width widens toward the semiconductor layer OS, and the facing insulating portion IP1 is also formed in a tapered shape similarly to the source electrode SE, as in the cases of FIG. 6 and FIG. 7. On the other hand, in the source electrode SE and the insulating portion IP1, an angle AN2 of the portion forming the tapered shape with respect to the semiconductor layer OS is, for example, 60 degrees. When the angle AN2 is, for example, in a low-taper shape between less than 60 degrees and 0 degrees or more, the facing insulating portion IP1 may also be formed in a low-taper shape, similar to the source electrode SE. When the source electrode SE and the insulating portion IP1 are both formed in a low-taper shape in this manner, no gap GP2 is formed between the source electrode SE and the insulating portion IP2 formed on the insulating portion, and the insulating layer IL6 is formed in a continuous manner.

Even when the insulating portion IP2 is formed in such a continuous manner, the first region AR1 in which the protective layer PL is provided includes the second region AR2 and the third region AR3. That is, as illustrated in FIG. 7 and FIG. 8, the shape of the insulating layer IL6 formed in the third region AR3 changes depending on the cross-sectional shape of the source electrode SE and the cross-sectional shape of the insulating portion IP1 facing the source electrode SE. And, even if the insulating portion IP2 is formed with the gap GP2 or is formed continuously, the protective layer PL can protect the first region AR1.

Moreover, the cross-sectional shape of the source electrode SE and the cross-sectional shape of the insulating portion IP1 facing thereof vary during the manufacturing process. For example, the contact hole CH1 has a circular shape in plan view. For this reason, it may be difficult to precisely form the surrounding of the contact portion PLG1, which is formed in a circular shape, into a low-taper shape. It is also conceivable to increase the volume and reduce the resistance by enlarging the cross-sectional shape of the source electrode SE. Accordingly, the cross section of the source electrode SE and the cross section of the insulating portion IP1 may be a high-taper shape, whether intentional or not. In this manner, even when there is a possibility that a gap GP2 will occur, the protective layer PL can protect the semiconductor layer OS. For the third region AR3 included in the first region AR1 protected by the protective layer PL, it is desirable to determine or estimate the size of the gap GP2 in advance, and set the size of the third region AR3 so that the gap GP2 is included.

### <Example of Formation of Protective Layer>

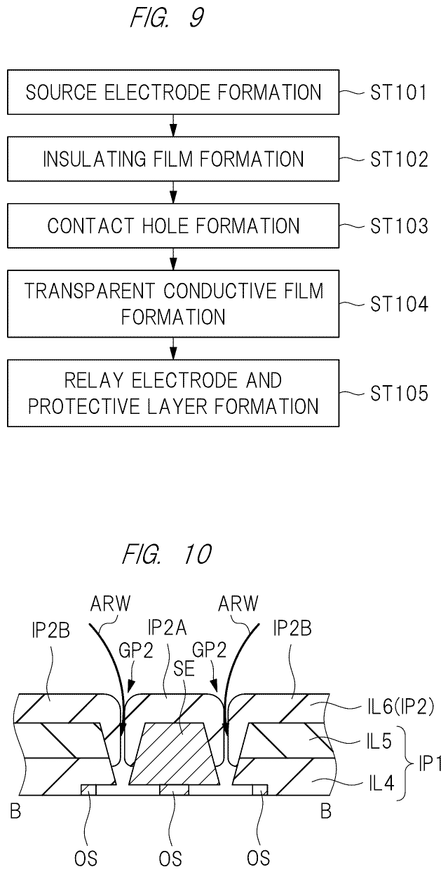

Next, an example of formation of the protective layer PL will be described. FIG. 9 is a flowchart illustrating the example of formation of the protective layer PL. In the following, among the steps of forming the entire liquid crystal display apparatus 1, steps related to the formation of the protective layer PL will be described in detail.

With the glass substrate 10, the insulating layer IL1, the insulating layer IL2, the gate electrode GE1, the insulating layer IL3, the semiconductor layer OS, the insulating layer IL4, the gate electrode GE2, the insulating layer IL5, and the contact hole CH1 formed, the source electrode SE is formed (ST101). The source electrode SE is formed along the Y-axis direction so as to pass over the contact hole CH1. The source electrode SE includes the contact portion PLG1. The contact portion PLG1 is formed in the contact hole CH1. The source electrode SE is electrically connected to the semiconductor layer OS via the contact portion PLG1. An insulating portion IP1 formed by the insulating layer IL4 and the insulating layer IL5 is formed on the side of the source electrode SE and on the semiconductor layer OS where the source electrode SE is not formed.

Next, the insulating layer IL6 (insulating portion IP2) is formed (ST102). The insulating layer IL6 is formed on the insulating layer IL5 and on the source electrode SE. For example, as illustrated in FIG. 6, the insulating layer IL6 is formed on the insulating layer IL5 and on the source electrode SE. The insulating layer IL6 is formed differently depending on the cross-sectional shape of the source electrode SE and the cross-sectional shape of the insulating layer IL5 adjacent to the source electrode SE. For example, as illustrated in FIG. 6, in the insulating layer IL6, the gap GP2 is formed between the insulating portion IP2A formed on the source electrode SE and the insulating portion IP2B formed on the insulating portion IP1. Further, as illustrated in FIG. 8, for example, the insulating layer IL6 is formed on the source electrode SE and the insulating layer IP1 in a continuous manner.

Next, the contact hole CH2 is formed (ST103). As illustrated in FIG. 5, the contact hole CH2 is formed so as to extend through the insulating layer IL4, the insulating layer IL5, and the insulating layer IL6 and expose the upper surface of the semiconductor layer OS. The position where the contact hole CH2 is formed is illustrated in, for example, FIG. 4 and FIG. 5.

Next, a transparent conductive film is formed (ST104). The region where the transparent conductive film is formed includes at least a relay region where the relay electrode RE is to be formed, and the first region AR1 where the protective layer PL is to be formed. The transparent conductive film is formed, for example, on the insulating layer IL6 and on the entire inner surface of the contact hole CH2. The transparent conductive film is made of a translucent conductive material such as ITO.

Next, the relay electrode RE and the protective layer PL are formed (ST105). For example, first, a resist is applied to the entire surface of the transparent conductive film. Next, the relay region where the relay electrode RE is to be formed and the region other than the first region AR1 where the protective layer PL is to be formed are exposed to light. The exposure reduces the melting property of the resist in the relay region and in the region other than the first region AR1. The resist in the region with reduced melting property is removed by development. As a result, the transparent conductive film is exposed in the relay region and in the region other than the first region AR1. Next, an etching solution is used to remove the transparent conductive film from the relay region where the resist is applied and from the region other than the first region AR1. At this point, the protective layer PL in a state where the resist is applied thereto is formed in the first region AR1. Therefore, for example, even if the gap GP2 is formed in the insulating layer IL6 as illustrated in FIG. 7, it is possible to prevent the etching solution from passing through the gap GP2 and permeating onto the semiconductor layer OS. Next, the resist applied to the relay region and the first region AR1 is removed. Accordingly, for example, as illustrated in FIG. 5, the relay electrode RE and the protective layer PL are formed on the insulating layer IL5. Description of the subsequent steps of forming the insulating layer IL7 etc. will be omitted.

In the liquid crystal display apparatus 1, by providing the protective layer PL for protecting the first region AR1, it is possible to prevent the etching solution used when forming the relay electrode RE from permeating into the semiconductor layer OS. Therefore, in the liquid crystal display apparatus 1, it is possible to avoid a situation in which the semiconductor layer OS is partially removed, and it is possible to prevent the occurrence of disconnections in the semiconductor layer OS.

### Differences from Comparative Example

FIG. 10 is a diagram illustrating a configuration example of a display apparatus, which is a comparative example, in which a protective layer PL is not provided. As illustrated in FIG. 10, the configuration example has the same configuration as that illustrated in FIG. 7 (that is, FIG. 6) except that the protective layer PL is not provided.

As illustrated in FIG. 10, a gap GP2 is formed between an insulating portion IP2A formed on a source electrode SE and an insulating portion IP2B formed on an insulating portion IP1. When the relay electrode RE is formed, since the protective layer PL is not provided, the etching solution permeates onto the semiconductor layer OS as illustrated by the arrows ARW in the drawing. As a result, the semiconductor layer OS partially disappears. This may result in a disconnection in the semiconductor layer OS.

In the liquid crystal display apparatus 1 of the present embodiment, the protective layer PL is provided. Due to this, it is possible to prevent the etching solution from permeating onto the semiconductor layer OS and occurrence of a disconnection in the semiconductor layer OS.

### <Other Example of Protective Layer PL>

The protective layer PL may be configured to prevent the etching solution from permeating into the semiconductor layer OS during the formation of the relay electrode RE. Therefore, for example, it is possible to configure the protective layer PL as follows.

### <Modification of Shape of Protective Layer PL in Plan View>

FIG. 11 is a plan view schematically illustrating another example of the protective layer PL. As illustrated in FIG. 11, the protective layer PL is formed in a circular shape in plan view. The protective layer PL includes a first region AR1. Therefore, the protective layer PL prevents the etching solution from penetrating into the semiconductor layer OS when the relay electrode RE is formed. Even if the protective layer PL is formed in this manner, the liquid crystal display apparatus 1 can prevent occurrence of a disconnection in the semiconductor layer OS. Since the protective layer PL is formed in a circular shape, a greater distance can be secured between the adjacent source electrode SE than in the case where the protective layer PL is formed in a rectangular shape. Therefore, a wider margin for misalignment of the protective layer PL can be secured, and the possibility of short-circuiting of the source electrode SE can be reduced.

Moreover, in plan view, the shape of the protective layer PL is not limited to the rectangular shape or the circular shape described above. For example, the shape of the first region AR1 may be a polygonal shape such as a triangle, a pentagon, or a trapezoid. The circular shape may be understood as a concept that includes an elliptical shape.

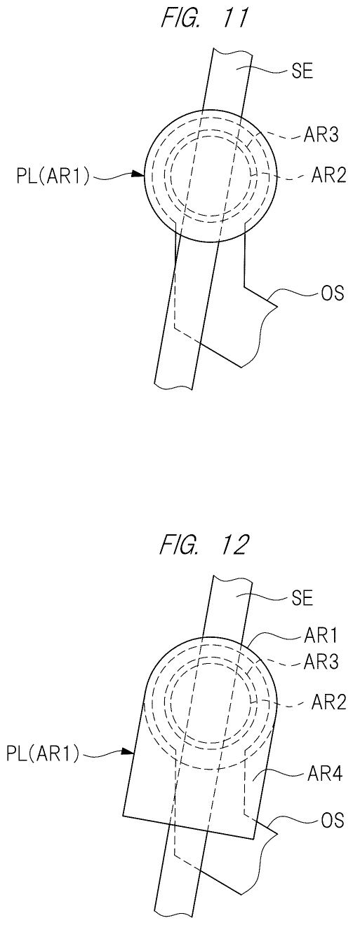

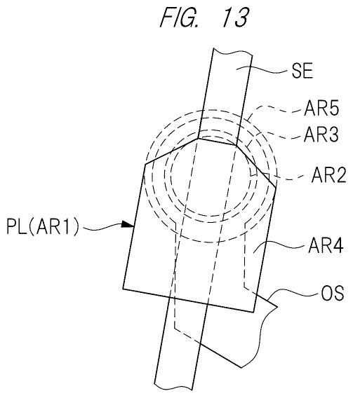

FIG. 12 is a plan view schematically illustrating another example of the protective layer PL. As illustrated in FIG. 12, the shape of the protective layer PL in plan view is a combined shape of the polygonal shape and the circular shape. FIG. 12 further illustrates a fourth region AR4 in which the source electrode SE and the semiconductor layer OS are connected and the semiconductor layer OS is drawn out from the connection region as wiring. As illustrated in FIG. 12, the first region AR1 protected by the protective layer PL includes the fourth AR4.

The protective layer PL protects the first region AR1. Even if the protective layer PL is formed in this manner, the liquid crystal display apparatus 1 can prevent occurrence of a disconnection in the semiconductor layer OS. Further, the first region AR1 protected by the protective layer PL includes the fourth region AR4 in plan view. Therefore, the protective layer PL can also prevent the etching solution from penetrating into wiring portion of the semiconductor layer OS when the relay electrode RE is formed. Therefore, the liquid crystal display apparatus 1 can more reliably prevent occurrence of a disconnection in the semiconductor layer OS.

FIG. 13 is a plan view schematically illustrating another example of the protective layer PL. As illustrated in FIG. 13, the first region AR1 is configured so as not to include a fifth region AR5. The fifth region AR5 is a part of the second region AR2 and the third region AR3 on the side opposite to the side where the semiconductor layer OS is drawn out as wiring. For example, the fifth region AR5 is a region opposite to the fourth region AR4 in plan view. In other words, the fifth region AR5 is a region most distant from the fourth region AR4 in the first region AR1.

Even if the fifth region AR5 is thus removed from the first region AR1, the wiring portion of the semiconductor layer OS is protected by the protective layer PL. This makes it possible to prevent the etching solution from penetrating into the wiring portion of the semiconductor layer OS during the relay electrode RE is formed. Even if the protective layer PL is formed so as to protect the first region AR1 except for the fifth region AR5, the liquid crystal display apparatus 1 can prevent occurrence of a disconnection in the semiconductor layer OS. Therefore, the liquid crystal display apparatus 1 can increase the tolerance for the accuracy of formation of the protective layer PL in plan view. This facilitates the formation of the protective layer PL.

The present invention is applicable to a display apparatus and an array substrate.

What is claimed is:

1. A display apparatus comprising:
a semiconductor layer;
a signal line provided on the semiconductor layer;
a first insulating portion provided on a side of the signal line;
second insulating portion provided on the first insulating portion and the signal line; and
a protective layer provided on the second insulating portion,
wherein, in plan view, a first region in which the protective layer is provided includes a second region in which the signal line is connected to the semiconductor layer, and a third region arranged in a surrounding of the second region in which the semiconductor layer is covered by the first insulating portion.

2. The display apparatus according to claim 1,
wherein the signal line includes a first contact portion connected to the semiconductor layer, and
wherein a shape of a cross-section of the signal line including the first contact portion in a width direction is a tapered shape in which a width thereof widens toward the semiconductor layer.

3. The display apparatus according to claim 2,
wherein, in the cross-section, an angle of a portion forming the tapered shape with respect to the semiconductor layer is 70 degrees or more and less than 90 degrees.

4. The display apparatus according to claim 1,
wherein a gap is formed between the second insulating portion formed on the signal line and the second insulating portion formed on the first insulating portion, and
wherein the protective layer covers the gap.

5. The display apparatus according to claim 1,
wherein the protective layer is provided on the second insulating portion and is provided so as not to be electrically connected thereto.

6. The display apparatus according to claim 1,
wherein a shape of the protective layer in plan view is any of a polygonal shape, a circular shape, and a combined shape of the polygonal shape and the circular shape.

7. The display apparatus according to claim 1, further comprising
a first electrode provided on the second insulating portion,
wherein the first electrode and the protective layer are provided away from each other on the second insulating portion, and
wherein the protective layer and the first electrode are made of indium tin oxide.

8. The display apparatus according to claim 7,
wherein the first electrode includes a second contact portion connected to the semiconductor layer, and
wherein the second contact portion extends through the first insulating portion and the second insulating portion and reaches the semiconductor layer.

9. The display apparatus according to claim 8, further comprising
a first gate electrode, a second gate electrode, and a pixel electrode,
wherein the semiconductor layer is provided above the first gate electrode and includes a portion provided below the second gate electrode,
wherein the pixel electrode includes a third contact connected to the first electrode above the second gate electrode, and
wherein the signal line is connected to a source electrode of the semiconductor layer.

10. An array substrate comprising:
a semiconductor layer;
a signal line provided on the semiconductor layer;
a first insulating portion provided on a side of the signal line;
a second insulating portion provided on the first insulating portion and the signal line; and
a protective layer provided on the second insulating portion,
wherein, in plan view, a first region in which the protective layer is provided includes a second region in which the signal line is connected to the semiconductor layer, and a third region arranged in a surrounding of the second region in which the semiconductor layer is covered by the first insulating portion.
